(19) United States
(12) Patent Application Publication
(10) Pub. No.: US 2011/0237054 A1
(43) Pub. Date: Sep. 29, 2011

(54) PLANAR NONPOLAR GROUP III-NITRIDE FILMS GROWN ON MISCUT SUBSTRATES

(75) Inventors: Kenji Iso, Kanagawa (JP); Hisashi Yamada, Ibaraki (JP); Makoto Saito, Ibaraki (JP); Asako Hirai, Santa Barbara, CA (US); Steven P. DenBaars, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/152,553

(22) Filed: Jun. 3, 2011

Related U.S. Application Data
(63) Continuation of application No. 12/189,026, filed on Aug. 8, 2008.
(60) Provisional application No. 60/954,744, filed on Aug. 8, 2007.
(60) Provisional application No. 60/954,767, filed on Aug. 8, 2007.

(51) Int. Cl. H01L 21/20

(52) U.S. Cl. 438/478; 257/E21.09

(57) ABSTRACT

A nonpolar III-nitride film grown on a miscut angle of a substrate. The miscut angle towards the <000-1> direction is 0.75° or greater miscut and less than 27° miscut towards the <000-1> direction. Surface undulations are suppressed and may comprise faceted pyramids. A device fabricated using the film is also disclosed. A nonpolar III-nitride film having a smooth surface morphology fabricated using a method comprising selecting a miscut angle of a substrate upon which the nonpolar III-nitride films are grown in order to suppress surface undulations of the nonpolar III-nitride films. A nonpolar III-nitride-based device grown on a film having a smooth surface morphology grown on a miscut angle of a substrate which the nonpolar III-nitride films are grown. The miscut angle may also be selected to achieve long wavelength light emission from the nonpolar film.

### CROSS REFERENCE TO RELATED APPLICATIONS

This application is a continuation under 35 U.S.C. Section 120 of U.S. Utility patent application Ser. No. 12/189,026, filed on Aug. 8, 2008, by Kenji Iso, Hisashi Yamada, Makoto Saito, Asako Hirai, Steven P. DenBaars, James S. Speck, and Shuji Nakamura, entitled “PLANAR NONPOLAR M-PLANE GROUP III-NITRIDE FILMS GROWN ON MISCUT SUBSTRATES” attorneys' docket number 30794.249-US-U1 (2008-004-2), which application claims the benefit under 35 U.S.C. Section 119(e) of U.S. Provisional Patent Application Ser. No. 60/954,744, filed on Aug. 8, 2007, by Kenji Iso, Hisashi Yamada, Makoto Saito, Asako Hirai, Steven P. DenBaars, James S. Speck, and Shuji Nakamura, entitled “PLANAR NONPOLAR M-PLANE GROUP III-NITRIDE FILMS GROWN ON MISCUT SUBSTRATES” attorneys' docket number 30794.249-US-P1 (2008-004-1), and U.S. Provisional Application Ser. No. 60/954,767, filed on Aug. 8, 2007, by Hisashi Yamada, Kenji Iso, Makoto Saito, Asako Hirai, Steven P. DenBaars, James S. Speck, and Shuji Nakamura, entitled “III-NITRIDE FILMS GROWN ON MISCUT SUBSTRATES,” attorney's docket number 30794.248-US-P1 (2008-062-1), which applications are incorporated by reference herein.

This application is related to the following and commonly-assigned U.S. patent applications:

U.S. Utility application Ser. No. 12/140,096, filed on Jun. 16, 2008, by Asako Hirai, Zhongyuan Jia, Makoto Saito, Hisashi Yamada, Kenji Iso, Steven P. DenBaars, Shuji Nakamura, and James S. Speck, entitled “PLANAR NONPOLAR M-PLANE GROUP III NITRIDE FILMS GROWN ON MISCUT SUBSTRATES,” attorney's docket number 30794.238 -US-U1 (2007-674-2), which application claims the benefit of U.S. Provisional Application Ser. No. 60/944,206, filed on Jun. 15, 2007, by Asako Hirai, Zhongyuan Jia, Makoto Saito, Hisashi Yamada, Kenji Iso, Steven P. DenBaars, Shuji Nakamura, and James S. Speck, entitled “PLANAR NONPOLAR M-PLANE GROUP III NITRIDE FILMS GROWN ON MISCUT SUBSTRATES,” attorney's docket number 30794.238-US-P1 (2007-674-1); and U.S. Utility application Ser. No. 12/189,038, filed on Aug. 8, 2008, by Hisashi Yamada, Kenji Iso, and Shuji Nakamura, entitled “NONPOLAR III-NITRIDE LIGHT EMITTING DIODES WITH LONG WAVELENGTH EMISSION,” attorney's docket number 30794.247-US-U1 (2008-063-2), now U.S. Pat. No. 7,847,280, issued Dec. 7, 2010, which application claims the benefit of U.S. Provisional Application Ser. No. 60/954,770, filed on Aug. 8, 2007, by Hisashi Yamada, Kenji Iso, and Shuji Nakamura, entitled “NONPOLAR III-NITRIDE LIGHT EMITTING DIODES WITH LONG WAVELENGTH EMISSION,” attorney's docket number 30794.247-US-P1 (2008-063-1);

which applications are incorporated by reference herein.

### BACKGROUND OF THE INVENTION

1. Field of the Invention

This invention relates to (1) a technique for the growth of planar nonpolar m-plane films, and more specifically, to a technique for the growth of an atomically smooth m-GaN film without any surface undulations, and (2) InGaN/GaN light emitting diodes (LEDs) and laser diodes (LDs), and more particularly to III-nitride films grown on miscut substrates in which the emission wavelength can be controlled by selecting the miscut angles.

2. Description of the Related Art

The usefulness of gallium nitride (GaN) and its ternary and quaternary compounds incorporating aluminum and indium (AlGaN, InGaN, AlInGaN) has been well established for fabrication of visible and ultraviolet optoelectronic devices and high-power electronic devices. These compounds are referred to herein as Group-III nitrides, or III-nitrides, or just nitrides, or by the nomenclature (Al,B,Ga,In) N. Devices made from these compounds are typically grown epitaxially using growth techniques including molecular beam epitaxy (MBE), metalorganic chemical vapor deposition (MOCVD), and hydride vapor phase epitaxy (HVPE).

GaN and its alloys are the most stable in the hexagonal wurtzite crystal structure, in which the structure is described by two (or three) equivalent basal plane axes that are rotated 120° with respect to each other (the a-axis), all of which are perpendicular to a unique c-axis. Group III and nitrogen atoms occupy alternating c-planes along the crystal's c-axis. The symmetry elements included in the wurtzite structure dictate that III-nitrides possess a bulk spontaneous polarization along this c-axis, and the wurtzite structure exhibits piezoelectric polarization.

Current nitride technology for electronic and optoelectronic devices employs nitride films grown along the polar c-direction. However, conventional c-plane quantum well structures in III-nitride based optoelectronic and electronic devices suffer from the undesirable quantum-confined Stark effect (QCSE), due to the existence of strong piezoelectric and spontaneous polarizations. The strong built-in electric fields along the c-direction cause spatial separation of electrons and holes that in turn give rise to restricted carrier recombination efficiency, reduced oscillator strength, and red-shifted emission.

One approach to eliminating the spontaneous and piezoelectric polarization effects in GaN optoelectronic devices is to grow the devices on nonpolar planes of the crystal. Such planes contain equal numbers of Ga and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes.

The other cause of polarization is piezoelectric polarization. This occurs when the material experiences a compressive or tensile strain, as can occur when (Al, In, Ga, B) N layers of dissimilar composition (and therefore different lattice constants) are grown in a nitride heterostructure. For example, a thin AlGaN layer on a GaN template will have in-plane tensile strain, and a thin InGaN layer on a GaN template will have in-plane compressive strain, both due to lattice matching to the GaN. Therefore, for an InGaN quantum well on GaN, the piezoelectric polarization will point in the opposite direction than that of the spontaneous polarization of the InGaN and GaN. For an AlGaN layer latticed matched to GaN, the piezoelectric polarization will point in the same direction as that of the spontaneous polarization of the AlGaN and GaN.

The advantage of using nonpolar planes over c-plane nitrides is that the total polarization will be reduced. There may even be zero polarization for specific alloy compositions on specific planes. Such scenarios will be discussed in detail in future scientific papers. The important point is that the polarization will be reduced compared to that of c-plane nitride structures.

Although high performance optoelectronic devices on nonpolar m-plane GaN have been demonstrated, it is known to be difficult to obtain a smooth surface in such materials. The m-plane GaN surface is typically covered with facets, or rather, macroscopic surface undulations. Surface undulation is mischievous, for example, because it originates faceting in quantum structures, and inhomogeneous incorporation of alloy atoms or dopants depend on the crystal facets, etc.

It has also been found to be difficult to obtain long wavelength emission from InGaN/GaN MQWs on such nonpolar m-plane GaN. This is probably due to low In incorporation of the InGaN/GaN MQWs. The emission wavelength of devices grown on m-plane is typically 400 nm, while the wavelength of devices grown on c-plane is 450 nm, at the same growth condition(s). Reducing the growth temperature increases the In incorporation; however, crystal quality would be degraded. This would be a significant problem for applications such as blue, green, yellow, and white LEDs.

The present invention describes a technique for the growth of group III-nitride films grown on miscut substrates. For example, blue emission has been obtained without degradation of the MQWs. The present invention also describes a technique for the growth of planar films of nonpolar m-plane nitrides. For example, an atomically smooth m-GaN film without any surface undulations has been demonstrated using the present invention. Thus, the present invention describes III-nitride films grown on miscut substrates in which the surface roughness, emission wavelength, and indium incorporation can be controlled by selecting the miscut angles.

### SUMMARY OF THE INVENTION

To overcome the limitations in the prior art described above, and to overcome other limitations that will become apparent upon reading and understanding the present specification, the present invention discloses a method for growing planar nonpolar III-nitride films that have atomically smooth surface without any macroscopic surface undulations, by selecting a miscut angle of a substrate upon which the nonpolar III-nitride films are grown in order to suppress the surface undulations of the nonpolar III-nitride films. The miscut angle may be an in-plane miscut angle towards the c-axis direction (e.g. <000-1> direction), and furthermore the miscut angle may be a 0.75° or greater miscut angle (with respect to an m-plane) towards the <000-1> direction and a less than 27° miscut angle (with respect to an m-plane) towards the <000-1> direction.

The present invention further discloses a nonpolar III-nitride film growth on a miscut of a substrate, wherein the miscut of the substrate provides a surface of the substrate angled at a miscut angle with respect to a nonpolar plane; and a top surface of the III-nitride film growth is substantially parallel to the surface.

A smooth surface morphology of the top surface may be determined by selecting the miscut angle of the substrate upon which the nonpolar III-nitride film is grown in order to suppress surface undulations of the nonpolar III-nitride film.

The miscut angle may be such that a root mean square (RMS) amplitude height of one or more undulations on a top surface of the film, over a length of 1000 micrometers, is 60 nm or less. The miscut angle may be such that a maximum amplitude height of one or more undulations on a top surface of the film, over a length of 1000 micrometers is 109 nm or less.

The miscut angle may be selected to increase indium incorporation into a III-nitride light emitting layer in the film, so that a peak wavelength of light emitted by the light emitting layer is increased to at least 425 nm.

A peak wavelength of light may be emitted by a III-nitride light emitting active layer in the film, in response to an injection current passing through the active layer, and the active layer's alloy composition, the nonpolar plane, and the miscut angle may be selected to reduce the polarization of the active layer so that the peak wavelength remains constant to within 0.7 nm of the peak wavelength for a range of injection currents. The range of currents may produce a range of intensities of the light emitted, and the maximum intensity may be at least 37 times the minimum intensity.

A device may be fabricated using the film. The device may be grown on the film having a surface morphology smooth enough for growth of the device.

The present invention further discloses a method of fabricating a III-nitride film, comprising providing a miscut of a substrate which is a surface of the substrate angled at a miscut angle with respect to a nonpolar plane; and growing a III-nitride film growth on the miscut of the substrate so that a top surface of the III-nitride film growth is substantially parallel to the surface of the substrate.

The present invention further discloses a method of emitting light, comprising emitting light from a nonpolar III-nitride film growth on a miscut of a substrate, wherein the miscut of the substrate is a surface of the substrate angled at a miscut angle with respect to a nonpolar plane, and a top surface of the III-nitride film growth is substantially parallel to the surface.

### BRIEF DESCRIPTION OF THE DRAWINGS

Referring now to the drawings in which like reference numbers represent corresponding parts throughout:

FIGS. 1(a)-(f) are optical micrographs of the surface of m-plane GaN films grown on freestanding m-GaN substrates, for various miscut angles toward <000-1>.

FIG. 2 shows root mean square (RMS) values evaluated from amplitude height measurements of an m-plane GaN surface, as a function of miscut angles on which the surface is grown.

FIG. 3 shows maximum amplitude height values evaluated from amplitude height measurement of an m-plane GaN surface, as a function of the miscut angle (toward <000-1>) upon which the surface is grown.

FIG. 4 is a cross sectional schematic of a III-nitride film, and subsequent device layers, on a miscut of a substrate.

FIG. 5 shows electroluminescence spectra of the LEDs grown on miscut substrates, for LED's grown on different miscut angles (miscut angles 0.01°, 0.45°, 0.75°, 1.7°, 5.4°, 9.6°, and 27°).

FIG. 6 shows electroluminescence (EL) spectra of an LED grown on a θ=5.4° miscut substrate, wherein, from bottom to top, the spectra are for an injection current of 1 mA, 2 mA, 5 mA, 10 mA, 20 mA, 30 mA, 40 mA, 50 mA, 60 mA, 70 mA, 80 mA, 90 mA, and 100 mA (i.e. intensity increases with current).

FIG. 7 shows electroluminescence intensity and peak wavelength vs. current, of a device grown on a θ=5.4° miscut substrate.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The present invention describes a method to obtain smooth surface morphology of nonpolar III-nitride films. Specifically, surface undulations of nonpolar III-nitride films are suppressed by controlling the miscut angle of the substrate upon which the nonpolar III-nitride films are grown.

Current nitride devices are typically grown in the polar [0001] c-direction, which results in charge separation along the primary conduction direction in vertical devices. The resulting polarization fields are detrimental to the performance of current state of the art optoelectronic devices.

Growth of these devices along a nonpolar direction has improved device performance significantly by reducing built-in electric fields along the conduction direction. However, macroscopic surface undulations typically exist on their surfaces, which is harmful to successive film growth.

Until now, no means existed for growing nonpolar III-nitride films without macroscopic surface undulations, even though they provide better device layers, templates, or substrates for device growth. The novel feature of this invention is that nonpolar III-nitride films can be grown as macroscopically and atomically planar films via a miscut substrate. As evidence, the inventors have grown {10-10} planar films of GaN. However, the scope of this invention is not limited solely to these examples; instead, the present invention is relevant to all nonpolar planar films of nitrides, regardless of whether they are homoepitaxial or heteroepitaxial.

The present invention further describes group III nitride films grown on miscut substrates in which the film's emission wavelength can be controlled by selecting the miscut angle. Specifically, In incorporation of III-nitride films is enhanced by selecting the miscut angle of the substrate upon which the III-nitride films are grown.

Prior to the present invention, the emission wavelength of the LEDs grown on on-axis m-plane was typically 400 nm, which limited applications for optical devices. An additional novel feature of this invention is that the enhancement of In incorporation of III-nitride films can be achieved via a growth on a miscut substrate. As evidence of this, the inventors have grown InGaN/GaN-based LEDs on miscut substrates. The emission wavelength of the film grown on an on-axis m-plane, (10-10), was 390 nm, while the emission wavelength of the film grown on a miscut with an angle of 0.75° or greater towards the <000-1> direction was 440 nm.

### Technical Description

### Using a Miscut to Grow Smooth III-Nitride Films

A first embodiment of the present invention comprises a method of growing planar nonpolar III-nitride films. In particular, the present invention utilizes miscut substrates in the growth process. For example, it is critically important that the substrate has a miscut angle in the proper direction for growth of both macroscopically and atomically planar {10-10} GaN.

In the first embodiment of the present invention, the GaN surfaces were grown using a conventional MOCVD method on a freestanding GaN substrate with a miscut angle toward the <000-1> direction. The thickness of the grown GaN film was 5 μm.

The miscut substrates were prepared by slicing from c-plane GaN bulk crystals. The miscut angles from the m-plane toward <000-1> were 0.01°, 0.45°, 0.75°, 5.4°, 9.6°, and 27°, which were measured by X-ray diffraction (XRD). The samples were grown in the same batch at different positions on the 2-inch wafer holder. The surface morphology was investigated by optical microscopy and amplitude height measurement.

### Experimental Results Illustrating Growth of Smooth Films

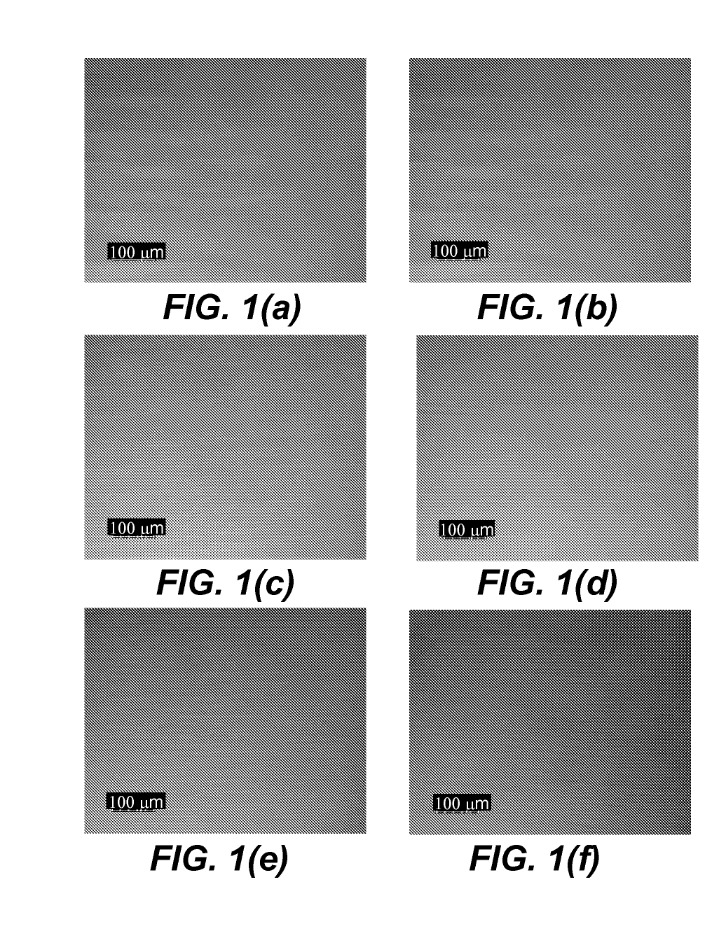

FIG. 1 shows optical micrographs of the surface of m-plane GaN film grown on freestanding m-GaN substrates with various miscut angles toward <000-1>. {10-10} GaN films grown on a substrate that is nominally on-axis has been found to have macroscopic surface undulations consisting of four-faceted pyramids. These pyramid facets are typically inclined to the a, c′ and c directions, as shown in FIGS. 1(a) and 1(b), wherein FIG. 1(a) has a miscut angle of 0.01° and FIG. 1(b) has a miscut angle of 0.45°. It was found that the surface on the substrate with the miscut angle of 0.75° or greater has smooth morphology as shown in FIG. 1(c), 1(d), 1(e), and 1(f), wherein FIG. 1(c) has a miscut angle of 0.75°, FIG. 1(d) has a miscut angle of 5.4°, FIG. 1(e) has a miscut angle of 9.6°, and FIG. 1(f) has a miscut angle of 27°.

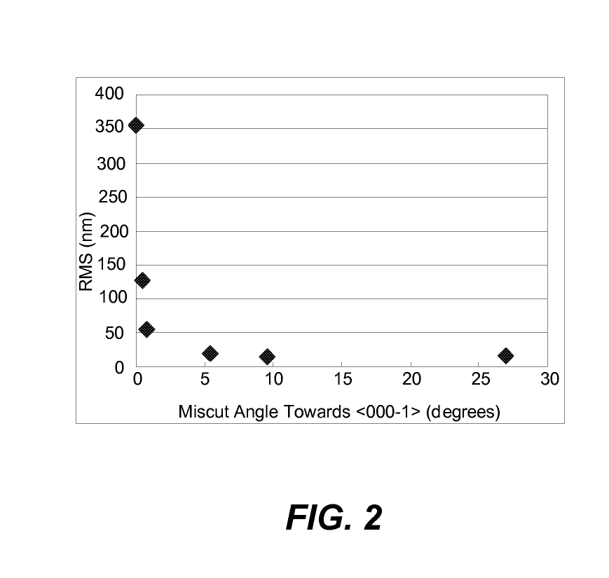

FIG. 2 shows Root Mean Square (RMS) values evaluated from amplitude height measurement of an m-plane GaN surface grown on various miscut angles. The RMS roughnesses over a 1000 μm length of the films on each of the miscut substrates were 356 nm, 128 nm, 56 nm, 19 nm, 15 nm, and 16 nm for the miscut angles of 0.01°, 0.45°, 0.75°, 5.4°, 9.6°, and 27° toward <000-1>, respectively. The RMS value was found to decrease with increasing miscut angle. In general, an RMS value less than 60 nm is expected for optoelectronic and electronic devices. Thus, it is preferable that a miscut angle of the substrate is 0.75° or greater.

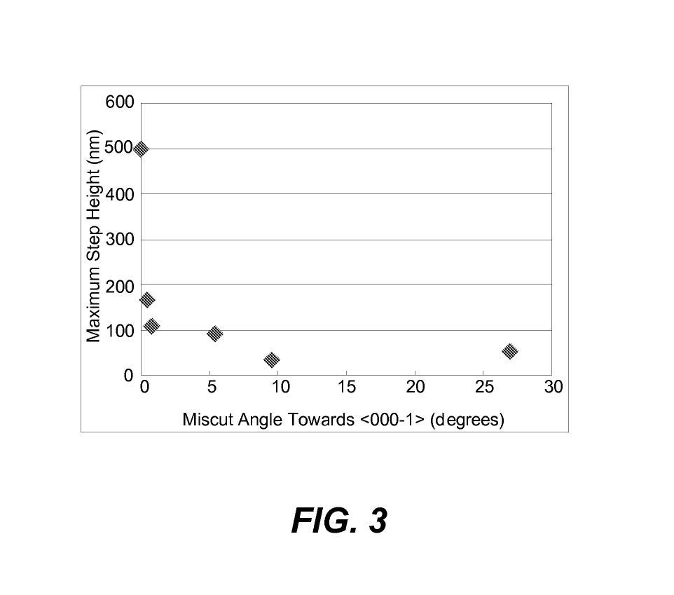

FIG. 3 shows maximum amplitude height values evaluated from amplitude height measurement of an m-plane GaN surface grown on the substrates with various miscut angles toward <000-1>. The maximum amplitude height values over a 1000 μm length of the films on each of the miscut substrates were 500 nm, 168 nm, 109 nm, 93 nm, 33 nm, and 52 nm for the miscut angles of 0.01°, 0.45°, 0.75°, 5.4°, 9.6°, and 27° toward <000-1>, respectively. The maximum amplitude height value was found to decrease with increasing miscut angle. Judging from FIG. 2, it is preferable that a miscut angle of the substrate is 0.75° or greater.

### Device Structures

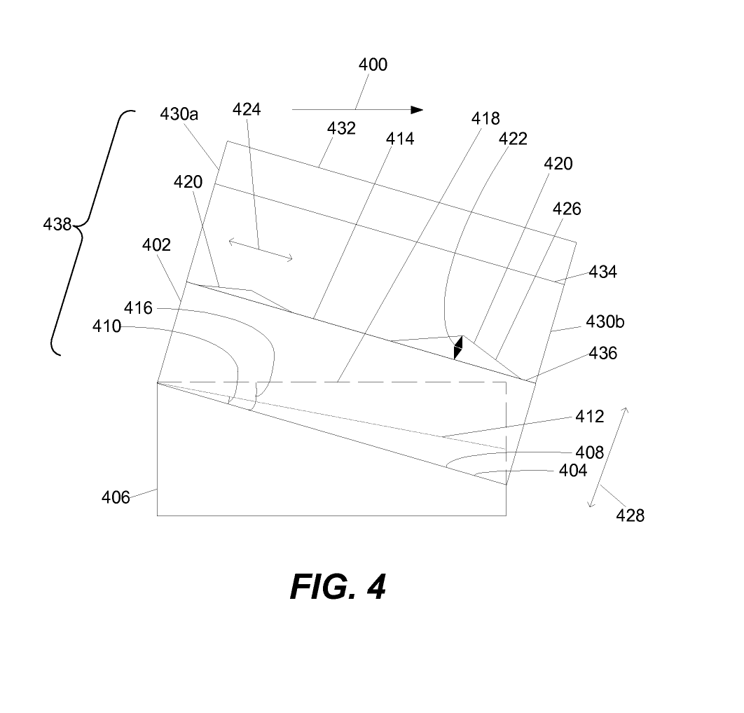

FIG. 4 is a cross sectional schematic along the c-direction 400 of a nonpolar III-nitride film growth 402 on a miscut 404 of a substrate 406 (e.g. Gallium Nitride), wherein the miscut 404 of the substrate 406 provides a surface 408 of the substrate 406 angled at a miscut angle 410 with respect to a nonpolar plane 412, a top surface 414 of the III-nitride film growth 402 is substantially parallel to the surface 408 of the substrate 406; and the miscut angle 410 is towards a c direction 400 (e.g. the <000-1> direction). The surface 414 may be a nonpolar plane.

FIG. 4 also illustrates a nonpolar III-nitride film growth 402 on a surface 408 (e.g. growth surface) of a substrate 406, wherein the surface 408 of the substrate 406 is at an orientation angle 416 with respect to a crystallographic plane 418 of the substrate 406; and a top surface 414 of the nonpolar III-nitride film 402 is angled at a miscut angle 410 with respect to a nonpolar plane (e.g. a-plane or m-plane) 412 of GaN (or III-nitride) and is substantially parallel to the surface 408 of the substrate 406.

The present invention discloses a method for achieving smooth films 402 by varying the miscut angle 410 and/or the miscut angle direction 400. The miscut angle 410 may be oriented towards a direction 400 of the surface undulations 420 in order to suppress the undulations 420. The top surface 414 of the nonpolar III-nitride film 402 may have a smooth surface 414 morphology that is determined by selecting a miscut angle 410 of a substrate 406 upon which the nonpolar III-nitride films 402 are grown in order to suppress surface undulations 420 of the nonpolar III-nitride films 402. For example, the miscut angle 410 towards the <000-1> direction 400 may be a 0.75° or greater miscut angle and a less than 27° miscut angle towards the <000-1> direction 400. The miscut angle 410 may be such that an RMS amplitude height 422 of one or more undulations 420 on the top surface 414 of the film 402, over a length 424 (of the surface 414) of 1000 micrometers, may be 60 nm or less. The miscut angle 410 may be such that a maximum amplitude height 422 of one or more undulations 420 on a top surface 414 of the film, over a length 424 of 1000 micrometers is 109 nm or less. The surface undulations 420 may comprise faceted pyramids (i.e. pyramids with facets 426). The thickness 428 of the film 402 is not limited to any particular thickness 428.

Other devices may be fabricated using the film 402. For example, the film 402 may be a substrate or template for subsequent III-nitride compound growth. A nonpolar III-nitride-based device (e.g. device layers 430a, 430b, such as quantum wells, barrier layers, transistor active layers, light emitting active layers, p-type layers, and n-type layers, etc.) may be grown on the film 402 having a smooth surface 414 morphology, wherein the film 402 is grown on a miscut angle 410 of the substrate 406.

The miscut angle 410 may be selected to suppress surface undulations 420 on the top surface 414, or within the nonpolar III-nitride film 402, to a level suitable for growth of optical devices. For example, subsequent growth of device layers 430a, 430b on the top surface 414 may lead to a top surface 432 of the device layers 430a, or interface(s) 434 between device layers 430a, 430b which are smooth enough to be a quantum well layer interface or light emitting layer interface, or epitaxial layer interface. The undulations 420 may be eliminated. After growth 430a, 430b on the surface 414, the surface 414 becomes an interface 436.

### Using a Miscut to Control Emission Wavelength

A second embodiment of the present invention also comprises III-nitride films utilizing miscut substrates in the growth process. In this embodiment, it is critically important that the substrate has a miscut angle in the proper direction to enhance In incorporation of the InGaN film.

In the second embodiment of the present invention, the epitaxial layers of the LED device were grown using a conventional MOCVD method on a freestanding GaN substrate with a miscut angle toward the <000-1> direction. The miscut substrates were prepared by slicing from c-plane GaN bulk crystals. The miscut angles from the m-plane toward <000-1> were 0.01°, 0.45°, 0.75°, 1.7°, 5.4°, 9.6°, and 27°, measured by X-ray diffraction (XRD). The samples were grown in the same batch at different positions on the 2-inch wafer holder. The LED structure, was comprised of a 5 μm-thick Si-doped GaN layer, 6-periods of GaN/InGaN MQW, a 15 nm-thick undoped Al_{0.15}Ga_{0.85}N layer, and 0.3 μm-thick Mg-doped GaN. The MQWs comprised 2.5 nm InGaN wells and 20 nm

GaN barriers. After the crystal growth of the LED structure, the samples were annealed for p-type activation and subsequently an n-and p-type metallization process was performed. The p-contact had a diameter of 300 μm and the emission properties were measured at room temperature.

### Experimental Results Illustrating Control of Emission Wavelength

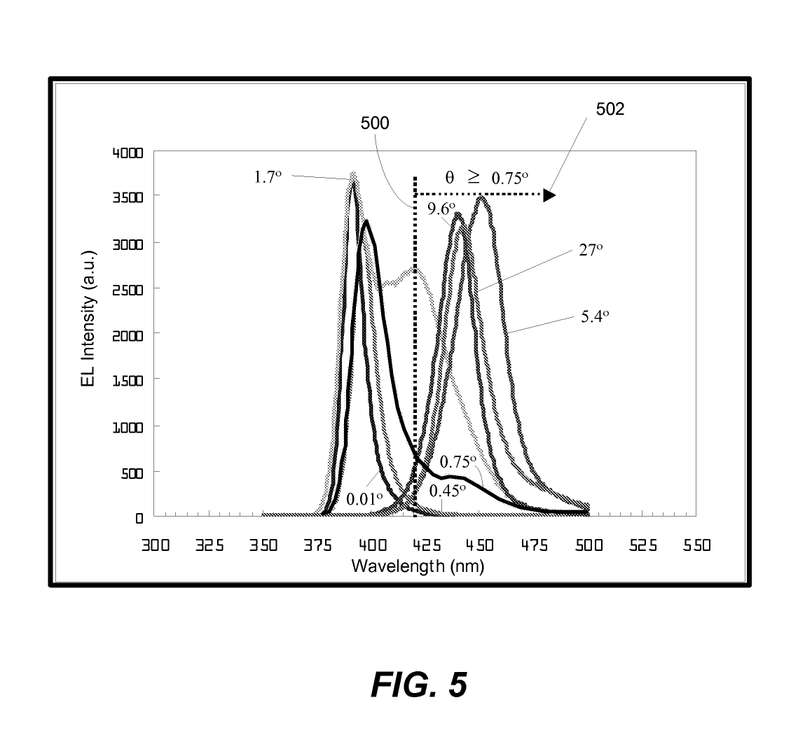

The electroluminescence (EL) spectra from the LEDs are shown in FIG. 5. The measurement was performed at a forward current of 20 mA (DC), at room temperature. The emission spectra of the InGaN/GaN MQWs grown on on-axis m-plane)(0.01°) and the substrate with a 0.45° miscut toward the <000-1> showed single peak emission around 390-395 nm. It was found that the emission intensity around 440 nm appeared to be increased by increasing the miscut angle from 0.75° toward the <000-1> direction. The peak emission wavelengths, measured at 20 mA, of the films on each miscut substrate were 391 nm, 396 nm, 396 nm, 395 nm, 454 nm, 440 nm, and 443 nm, for mis-orientation angles (or miscut angles) of 0.01°, 0.45°, 0.75°, 1.7°, 5.4°, 9.6°, and 27°, respectively. It was also found that the data for the miscut angle of 0.75° has a second peak at a wavelength of 421 nm. This wavelength (421 nm) was shorter than the others (440-452 nm); however this is caused by the growth temperature variation in the 2 inch wafer holder. Thus it is possible to obtain long wavelength emission via substrates with miscut angles of 0.75° or greater. Spectra to the right of the imaginary vertical line 500, as shown by the arrow 502, were obtained for LEDs on a substrate with a miscut angle θ0.75°.

Thus, FIG. 5 shows how the miscut angle 410, θ may be selected (e.g. greater than or equal to 0.75°) to increase indium incorporation into a III-nitride light emitting layer (such as an active layer 430b comprising InGaN quantum well(s) sandwiched between GaN barriers) in the film 438 or on the film 402, so that a peak wavelength of light emitted by the light emitting layer is increased beyond 425 nm (at least 425 nm), for example. Typically, the light emission results from electron-hole pair recombination between an electron in a quantum well state in the conduction band of the light emitting layer 430b and a hole in quantum well state in the valence band of the light emitting layer 430b. Typically, the more indium in the active layer, the smaller the bandgap of the active layer and therefore the longer emission wavelength can be achieved from the active layer.

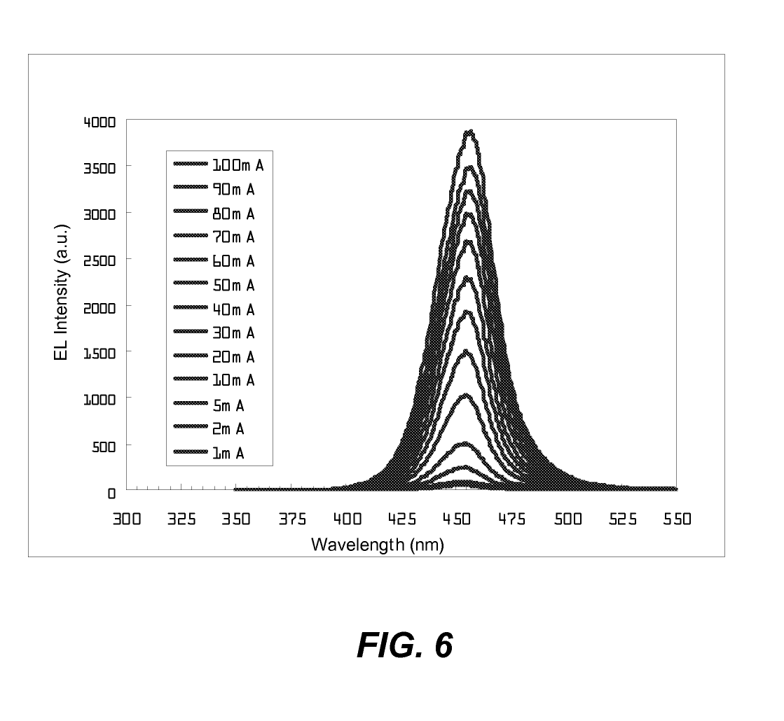

FIG. 6 shows the EL spectra of the LED grown on a substrate with a miscut angle of 5.4°, for various injection currents. It was found that all spectra showed a single peak wavelength around 454 nm.

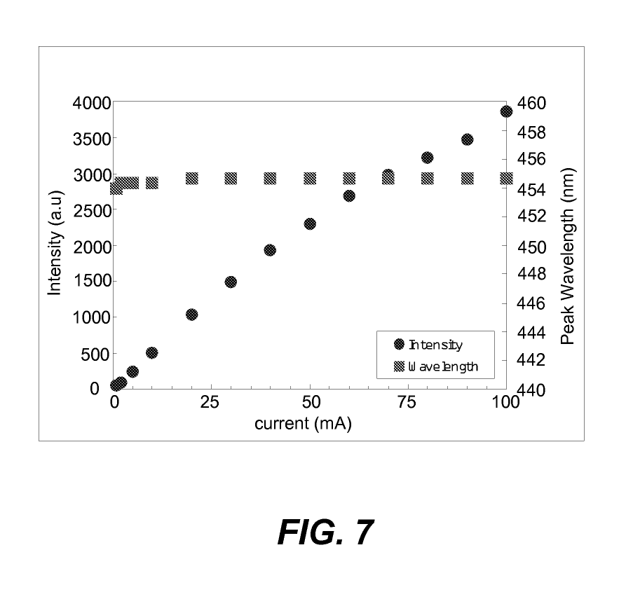

The EL intensity and peak wavelength as a function of injection current is shown in FIG. 7. The peak wavelength was almost constant in the applied range, indicating that the effect of polarization is significantly reduced.

### Device Structures

FIG. 4 is also illustrates a III-nitride light emitting active layer 430b which may emit a peak wavelength of light in response to an injection current passing through the light emitting layer 430b. The light emitting layer's 430b alloy composition (including indium composition or content), and/or the particular nonpolar plane 412, and/or the miscut angle 410, may be selected to reduce the polarization of the layer 430b so that the peak wavelength remains substantially constant for a range of injection currents, as shown by FIGS. 6 and 7.

For example, an m-plane 412, a miscut angle 410 of 5.4°, and a light emitting active layer 430b comprising an InGaN alloy composition of quantum wells would produce a nonpolar light emitting layer 430b with reduced polarization so that (or characterized by) the peak wavelength of light emitted by the active layer 430b remains constant to within (but not limited to) 0.7 nm of the peak wavelength for a range of injection currents. The range of injection currents may be 0 to 100 mA, or the range of injection currents may be sufficient to produce a range of intensities emitted by the active layer 430b such that the maximum intensity is at least 37 times the minimum intensity (i.e. the maximum current in the range produces a maximum intensity at least 37 times the minimum intensity produced by the minimum current). However, other ranges of current and ranges of intensity are envisaged, for example, current ranges and intensity ranges typically used in III-nitride semiconductor LEDs. Moreover, the degree to which the peak wavelength remains constant for the range of currents or intensities may be modified, and is a measure of the degree of polarization and nonpolarity of the light emitting layer 430b (i.e. the more the peak wavelength remains constant over a wider range of currents, the more nonpolar the light emitting layer 430b is). The peak wavelength may remain substantially constant over the range of intensities and currents.

This technique may be used to characterize the nonpolarity of III-nitride films in general, including non light emitting III-nitride layers, or passive (e.g. optically pumped) layers. For example, a III-nitride layer having a substantially similar alloy composition as the light emitting layer 430b, and a substantially similar miscut angle 410 with respect to a substantially similar nonpolar plane 412, may have the same degree of nonpolarity as the light emitting layer III-nitride layer 430b described above.

The device may further comprise a p-type layer 430a and an n-type layer 402, wherein the active layer 430b comprises at least one nonpolar InGaN quantum well (sandwiched by GaN barriers) between the p-type layer 430a and the n-type layer 402. The miscut angle 410 may be selected so that the active layer 430b emits light comprising a peak wavelength above 425 nm (for example) when an injection current passes between the n-type layer 402 and the p-type layer 430a. However, other nitride based quantum wells and barriers are also envisaged.

### Possible Modifications and Variations

In addition to the miscut GaN freestanding substrates 406 described above, foreign substrates 406, such as m-plane SiC, ZnO, and γ-LiAlO₂, can be used as a starting material as well. Any substrate suitable for growth of nonpolar III-nitride compounds may be used, although buffer layers may be required.

Although the present invention has been demonstrated using InGaN/GaN films 402, AlN, InN or any related alloy (e.g. III-nitride compound) can be used as well.

The present invention is not limited to the MOCVD epitaxial growth method described above, but may also use other crystal growth methods, such as HVPE, MBE, etc.

In addition, one skilled in this art would recognize that these techniques, processes, materials, and miscut angles, etc., would also apply to miscut angles in other directions 400, such as the <0001> direction, a-axis direction, with similar results.

The film 402 may be a substrate for subsequent layers 430a and 430b, or the film 438 itself, may comprise the device or the device layers 430a,430b. For example, the film 402 may comprise an n-type layer (e.g. an n-type GaN film), or the film 438 may comprise the active layer 430b (e.g. light emitting layer), the p-type layer 430a, and the n-type layer 402, wherein the active layer 430b is between the p-type layer 430a and the n-type layer 402. In either case, the film 402, 438 is a nonpolar III-nitride film growth 402,438 on a miscut 404 of a substrate 406, wherein the miscut 404 of the substrate 406 is a surface 408 of the substrate 406 angled at a miscut angle 410 with respect to a nonpolar plane 412, a top surface 414,432 of the III-nitride film growth 402, 408 is substantially parallel to the surface 408 of the substrate 406. Interfaces 434, 436 of layers within the film 438 may also be substantially parallel to the surface 408.

Additional layers may be used, for example, the n-type layer may be an additional layer between the film 402 and the active layer 430b, or additional barrier layers (or an AlGaN layer) may be between the p-type layer 430a and the active layer 430b, for example. Proper n-type contacts and p-type contacts may be made to the n-type layer and p-type layer respectively, for example.

Although a particular example of an LED structure is presented above, the present invention is not limited to a particular device structure.

### Advantages and Improvements

The on-axis m-plane GaN epitaxial layers always have pyramid shaped features 426 on their surfaces. By controlling the crystal miscut direction 400 and angle 410, extra smooth surfaces 414 can be obtained, and thus high quality device structures 430a, 430b can be achieved.

For example, a laser diode comprising layers 430a, 430b with smooth quantum well interfaces 434, 436 would enhance the device's performance. In another example, a smooth interface 434, 436 for heterostructure epi devices, such as high electron mobility transistors (HEMTs) or heterojunction bipolar transistors (HBTs), would reduce carrier scattering and allow higher mobility of the two dimensional electron gas (2DEG). Overall, the present invention would enhance the performance of any device where active layer flatness is crucial to the device performance.

In addition, the enhanced step-flow growth mode via a miscut substrate could suppress defect formation and propagation typically observed in GaN films with a high dopant concentration. Moreover, this would enlarge the growth window of m-GaN, which would result in a better yield during manufacture and would also be useful for any kind of lateral epitaxial overgrowth, selective area growth, and nanostructure growths.

In addition, prior to the present invention, the wavelength of InGaN/GaN MQW grown on on-axis m-plane GaN epitaxial layers was limited to around 400 nm. By controlling the crystal miscut direction and angle, enhancement in In incorporation can be obtained, and thus long wavelength emission of the structures can achieved.

For example, blue, green, yellow, and white LEDs without polarization effects would enhance the devices' performance. In another example, In-containing devices, such as high electron mobility transistors (HEMTs) or heterojunction bipolar transistors (HBTs), would also have enhanced device performance using the films of the present invention. Overall, the present invention would enhance the performance of any device.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a III-nitride film, comprising:
providing a miscut of a substrate which is a surface of the substrate angled at a miscut angle with respect to a nonpolar plane; and
growing a III-nitride film growth on the surface of the substrate so that a top surface of the III-nitride film growth is substantially parallel to the surface of the substrate;
wherein the top surface has a smooth surface morphology that is determined by selecting the miscut angle of the substrate upon which the nonpolar III-nitride film is grown in order to suppress surface undulations of the nonpolar III-nitride film.

2. The method of clam 1, wherein the miscut angle is towards a c direction.

3. The method of clam 2, wherein the c direction is a <000-1> direction.

4. The method of clam 1, wherein the miscut angle towards the <000-1>direction is 0.75° or greater and less than 27°, and the nonpolar plane is m-plane.

5. The method of clam 1, wherein the miscut angle is such that a root mean square (RMS) amplitude height of one or more of the surface undulations on the top surface of the film, over a length of 1000 micrometers, is 60 nm or less.

6. The method of clam 1, wherein the miscut angle is such that a maximum amplitude height of one or more of the surface undulations on the top surface of the film, over a length of 1000 micrometers is 109 nm or less.
